(19) United States
(12) Patent Application Publication
(10) Pub. No.: US 2025/0237722 A1
(43) Pub. Date: Jul. 24, 2025

(54) RADIO FREQUENCY SIGNAL RECEPTION SYSTEM FOR MAGNETIC RESONANCE IMAGING

(71) Applicant: SHENZHEN INSTITUTES OF ADVANCED TECHNOLOGY CHINESE ACADEMY OF SCIENCES, Shenzhen (CN)

(72) Inventors: Ye LI, Shenzhen (CN); Zhiguang MO, Shenzhen (CN); Chao LUO, Shenzhen (CN); Hairong ZHENG, Shenzhen (CN)

(73) Assignee: SHENZHEN INSTITUTES OF ADVANCED TECHNOLOGY CHINESE ACADEMY OF SCIENCES, Shenzhen (CN)

(21) Appl. No.: 19/063,710

(22) Filed: Feb. 26, 2025

Related U.S. Application Data
(63) Continuation of application No. PCT/CN2023/099936, filed on Jun. 13, 2023.

(51) Int. Cl. G01R 33/34; G01R 33/36

(52) U.S. Cl. CPC G01R 33/3403; G01R 33/34007; G01R 33/3621

(57) ABSTRACT

A radio frequency signal reception system for magnetic resonance imaging includes a cryostat, a coil and a pre-amplifier. The cryostat is provided with a housing, a thermal insulation cover and a vacuum layer which is covered by the housing, the vacuum layer is communicated with the first pumping port, the coil is arranged in the closed cavity, and a signal generated by the coil is transmitted to the magnetic resonance system through the pre-amplifier. The radio frequency signal reception system provided by the application has the advantages of high signal-to-noise ratio, wide applicability, easy operation, and easy maintenance, and is suitable for imaging multiple parts of the human body such as knee joints, arms, and wrists.

### CROSS-REFERENCE TO RELATED APPLICATIONS

This application is a continuation application of International Application No. PCT/CN2023/099936, filed on Jun. 13, 2023, the entire contents of which are incorporated herein by reference.

### TECHNICAL FIELD

The application relates to the technical field of magnetic resonance imaging, in particular to a radio frequency signal reception system for magnetic resonance imaging.

### BACKGROUND

Magnetic resonance imaging (MRI) has become an important means of soft tissue imaging because of its advantages of non-invasive, non-radiation, high-resolution, high-contrast and arbitrary orientation cross-section imaging. During magnetic resonance imaging, the magnetic resonance imaging system sends a magnetic resonance signal to the human body through the transmitting coil, and after the human tissue is excited by the signal, the feedback electromagnetic signal is fed back to the system through the reception coil. The signal strength received by the reception coil largely determines the quality of the reconstructed image.

Signal-to-noise ratio is the core parameter of coil design. High signal-to-noise ratio means higher resolution and higher contrast, which means better image quality. The stronger the intensity of the signal fed back by the human body received by the coil is, and the smaller the thermal noise of the reception coil itself is, the higher the signal-to-noise ratio is, and the better the reception performance is. The former requires the coil or resonant structure to be as close as possible to the imaging site, while the latter can be achieved by reducing the temperature of the coil and circuit.

At present, the coil products on the market work at room temperature, and the thermal noise of the coil and related circuits limits the improvement of the signal-to-noise ratio. For example, Chinese Patent Application Publication CN103116147A discloses a knee radio frequency coil for a magnetic resonance imaging system that reduces noise by placing the coil in a cryogenic environment, resulting in an improved signal-to-noise ratio. However, the scheme has the following defects.

Firstly, it is not conducive to the debugging of the radio frequency coil in the manufacturing process. Different from the common mass production products, for the magnetic resonance coil, a small difference in the value of a component will cause the coil not to be in the best working state, or even completely unable to work, and the current component production process is far from guaranteeing that the actual value is completely consistent with the nominal value. In addition, when the capacitor and other components are immersed in liquid nitrogen, the capacitance value usually changes because the electromagnetic parameters of the capacitor material are affected by temperature changes, so the production of the magnetic resonance coil at low temperature cannot be separated from the repeated manual measurement and debugging according to its state. Even for experienced engineers, this process can take weeks or even months. In the existing technology, the realizability, easy operation and subsequent easy maintenance of the coil debugging are less considered.

Secondly, it is only used as a single coil, and its imaging quality is acceptable for larger imaging parts such as the knee joint, but the imaging quality of smaller imaging parts such as the wrist will be reduced.

Lastly, the bird cage coil design is used in the coil part, which usually brings difficulties in debugging due to its high requirements for symmetry, and if the debugging is not good, it may cause a sharp decline in signal uniformity.

In the prior art, the article “Adaptive Cylindrical Wireless Metasurfaces in Clinical Magnetic Resonance Imaging” (Chi, et al. ADVANCED MATERIALS, vol. 33, no. 41, 2021) takes the body coil as the reception coil. Meanwhile, the imaging part is wrapped with a matesurface to enhance the signal and ultimately improve the received signal-to-noise ratio. The scheme is effective for smaller imaging parts, such as the wrist, or animals such as mice, but is not suitable for imaging larger body parts. In addition, the body coil is used as the reception coil in this scheme, because the signal of the body coil itself is relatively weak, there is still room for improvement in the obtained system signal-to-noise ratio.

### SUMMARY

The purpose of the present application is to overcome the shortcomings of the existing technology and provide a radio frequency signal reception system for magnetic resonance imaging. comprising a cryostat, a coil and a pre-amplifier, wherein the cryostat is provided with a housing, a thermal insulation cover and a vacuum layer which is covered by the housing, the vacuum layer comprises a vacuum region and a closed cavity surrounding the vacuum region, and the vacuum layer is communicated with a first pumping port, the coil is arranged in the closed cavity, and a signal generated by the coil is transmitted to the magnetic resonance system through the pre-amplifier.

In one embodiment, the insulation cover comprises a cavity, and is provided with a second pumping port, and the cavity of the insulation cover is vacuumized through the second pumping port.

In one embodiment, the cavity of the insulation cover is filled with a heat insulation material to insulate the heat.

In one embodiment, the coil is a local coil, liquid nitrogen is injected into the closed cavity to form a liquid nitrogen cavity, and the injected liquid nitrogen overflows the coil.

In one embodiment, the coil is a semi-flexible circuit board on which the coil array and associated circuitry are etched, and the coil is inserted along the liquid nitrogen cavity and then connected end to end.

In one embodiment, the housing, the insulation cover and the closed cavity are all made of non-magnetic non-metallic materials.

In one embodiment, the non-metallic material includes glass fiber reinforce plastics or thermoplastic materials.

In one embodiment, the insulation cover is provided with a pressure relief port, which passes through the insulation cover and is communicated with the closed cavity, a cable exits through the pressure relief port, and the cable does not completely block the pressure relief port.

In one embodiment, the system further comprises, when imaging the target part, overlaying the target part with a signal-enhancing layer made of a resonance circuit or high dielectric material sized to accommodate the target part.

In one embodiment, the thermoplastic material is a 3D printed material.

Compared with the prior art, the application has the advantages that aiming at the radio frequency signal reception system, the special cryostat is designed, and the open type design is used, thereby being beneficial to the repeated debugging of the radio frequency coil in the manufacturing process, and no additional refrigeration equipment is needed. In addition, it can also be matched with the signal improvement layer to adapt to the imaging of different sizes, so as to meet the different needs of signal amplification and electromagnetic distribution improvement. The radio frequency signal reception system capable of improving the imaging performance in various application scenes is formed by combining the radio frequency coil at low temperature with the signal improvement layer, and is particularly suitable for imaging parts with different sizes such as knee joints, arms and wrists of a human body.

Other features and advantages of the present application will become apparent from the following detailed description of exemplary embodiments of the application with reference to the figures.

### BRIEF DESCRIPTION OF THE DRAWINGS

The figures, which are incorporated in and constitute a part of the specification, illustrate embodiments of the application and, together with the description, serve to explain the principles of the application.

FIG. 1 is a front view of a radio frequency signal reception system according to one embodiment of the present application.

FIG. 2 is a cross-sectional view of a radio frequency signal reception system according to one embodiment of the present application.

FIG. 3 is another cross-sectional view of a radio frequency signal reception system according to an embodiment of the present application.

FIG. 4 is a schematic diagram illustrating an operation of a radio frequency signal reception system according to an embodiment of the present application.

FIG. 5 is a schematic diagram of coil insertion according to one embodiment of the present application.

### DETAILED DESCRIPTION OF THE EMBODIMENTS

Various exemplary embodiments of the present application will now be described in detail with reference to the figures. It should be noted that the relative arrangement of parts and steps, the numerical expressions, and the numerical values set forth in these embodiments do not limit the scope of the application unless specifically stated otherwise.

The following description of at least one exemplary embodiment is merely illustrative in nature and is in no way intended to limit the application, its application, or uses.

Techniques, methods, and devices known to those of ordinary skill in the pertinent art may not be discussed in detail, but should be considered part of the specification, where appropriate.

In all instances shown and discussed herein, any particular value is to be construed as merely illustrative and not restrictive. Thus, other examples of example embodiments may have different values.

It should be noted that like reference numbers and letters refer to like items in the following figures, and therefore, once an item is defined in one figure, it needs not be further discussed in subsequent figures.

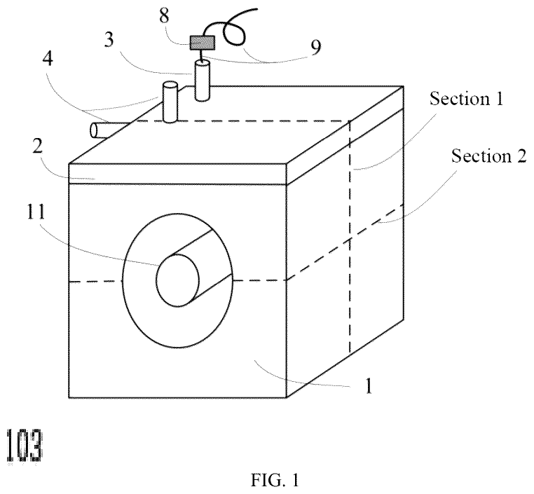

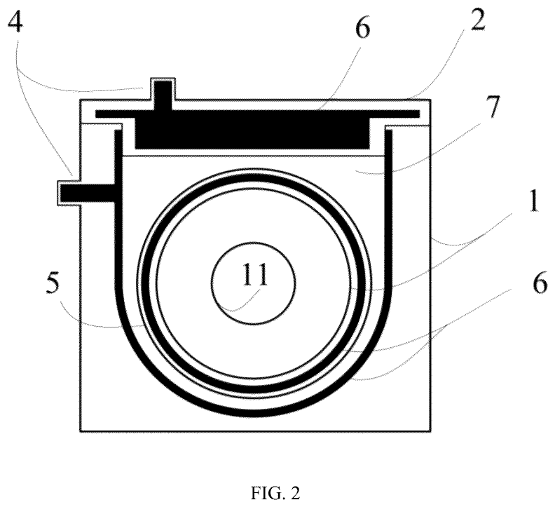

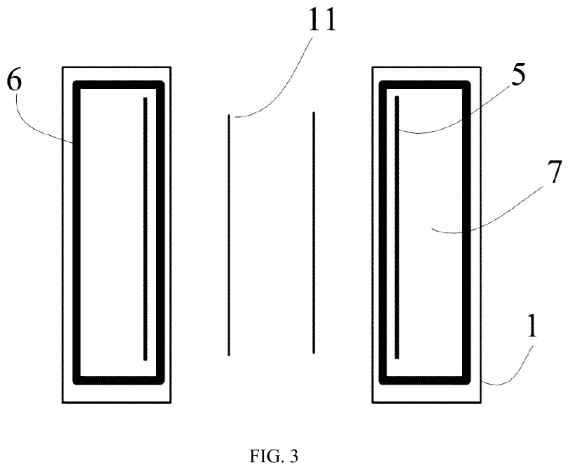

As shown in FIG. 1, FIG. 2 and FIG. 3, the multi-channel radio frequency signal reception system for magnetic resonance imaging comprises a cryostat, a coil 5 accommodated in the cryostat, and a pre-amplifier 8 disposed outside the cryostat. In the example of FIG. 1, the cryostat is provided with a housing 1, an insulation cover 2 and a vacuum layer 6. The housing 1 may enclose the vacuum layer 6 as shown in FIG. 2, or may be merely a support. The shape of the housing 1 is not limited to the one shown in the figures, but may be another shape adapted to play a supporting role.

The vacuum layer 6 illustrated in FIG. 2 comprises a vacuum region and a closed cavity (not shown) surrounding the vacuum region. The insulation cover 2 contains a vacuum cavity which can be vacuumized through a vacuum pumping port 4. For example, two vacuum pumping ports 4 are provided, one of which is provided on the thermal insulation cover 2 and is communicated with the vacuum cavity of the thermal insulation cover 2, and the other of which is provided on the side of the housing 1 and is communicated with the vacuum layer 6 in the cryostat. It should be understood that the insulation cover 2 is not limited to being heat-insulated by a vacuum cavity, but may be heat-insulated by filling a material such as foam. By performing heat insulation treatment on the insulation cover 2, the cryostat can have a better heat insulation effect to ensure that the cryostat does not absorb heat from the outside, thereby effectively maintaining a low temperature environment. In addition, the designed cryostat does not need additional cooling equipment, thereby reducing the cost.

In FIG. 1, the cryostat is further provided with a pressure relief port 3, a cable 9 connected to the pressure relief port, and a pre-amplifier 8 connected to the cable 9.

In one embodiment, a liquid nitrogen cavity 7 is formed between the vacuum layers 6. When the system is working, the injected liquid nitrogen needs to cover (submerge) the coil 5. The vacuum pumping port 4 is communicated with the vacuum layer 6.

In one embodiment, the entire cryostat may be made of a non-magnetic material. For example, the housing 1, the insulation cover 2 and the vacuum cavity are all made of non-magnetic non-metallic materials. For example, glass fiber reinforced plastics or other 3D printing materials that meet the requirements of strength and compactness can be used. As long as these materials meet the requirements of non-magnetic, non-metallic, enough to form a vacuum environment, no magnetic resonance signal or magnetic resonance signal is not enough to affect the imaging effect.

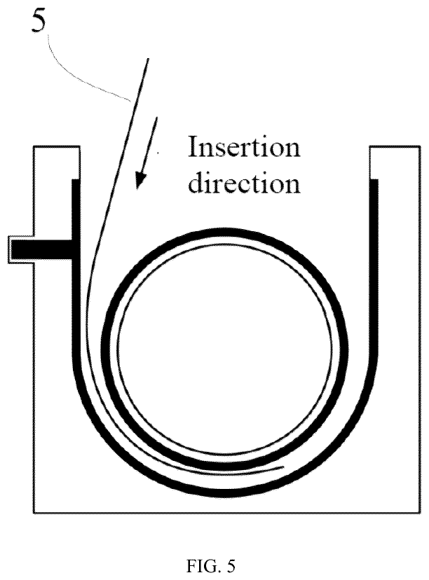

In one embodiment, the coil 5 is a semi-flexible circuit board on which the coil array and associated circuitry are etched. During installation, the coil 5 can be inserted along the liquid nitrogen cavity 7 and then connected end to end to complete the installation of the coil, as shown in FIG. 5. The coil 5 is connected to a pre-amplifier 8, and the cooled coil obtains a signal with a high signal-to-noise ratio, which is transmitted to a magnetic resonance system for processing via cable 9 and the pre-amplifier 8. The pressure relief port 3 is communicated with the liquid nitrogen cavity 7 through the thermal insulation cover 2, and the cable 9 exits through the pressure relief port 3, and the cable 9 should not completely block the pressure relief port 3.

In practical applications, in order to adapt to the imaging of parts of different sizes, the signal improvement layer can also be used to image the target part. For example, the signal improving layer 11 may be realized by a resonance circuit or may be realized by a high dielectric material. Where the signal improvement layer 11 is of a resonance circuit structure, the signal improvement layer amplifies the signal fed back by the detected part, so as to improve the signal strength of the radio frequency signal reception system, thereby improving the signal-to-noise ratio. Where the signal improvement layer 11 is made of a high dielectric material, the function is to improve the distribution of the electromagnetic field at the measured portion to make it more uniform, thereby obtaining a higher quality image. Under the ultra-high field strength such as 5T and 7T (T is the unit of magnetic field strength Tesla), the higher the field strength is, the more significant the image quality effect is.

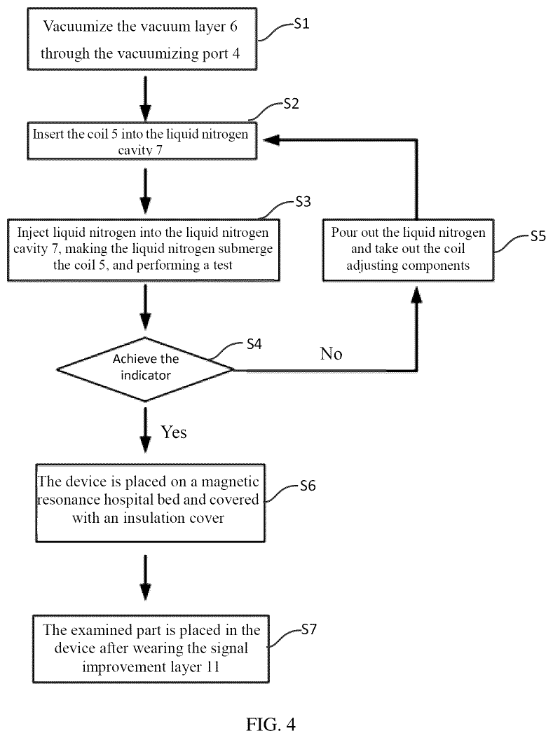

For further understanding of the present application, referring to FIG. 4, an operation process of the provided multi-channel radio frequency signal reception system for magnetic resonance imaging includes the following steps:

S1, vacuumizing the vacuum layer 6 through the vacuumizing port 4;

S2, inserting the coil 5 into the liquid nitrogen cavity 7;

S3, injecting liquid nitrogen into the liquid nitrogen cavity 7, making the liquid nitrogen submerge the coil 5, and performing a test;

S4, judging whether the signal-to-noise ratio of the coil reaches the set indicator;

S5, if the set indicator is not reached, the liquid nitrogen is poured out, the coil adjusting components are taken out, and then continuing with Step S2;

S6, if the set indicator is reached, the device is placed on the magnetic resonance hospital bed and covered with an insulation cover; and

S7, the examined part is placed in the device after wearing the signal improvement layer 11.

It should be understood that those skilled in the art can make appropriate changes or modifications to the above embodiments without departing from the spirit and scope of the present application. For example, the cryogenic coil is not limited to being used with the signal improvement layer, and the cryogenic coil may be used alone. For another example, it is not limited to being used for human body imaging, but is also applicable to animal imaging. In addition, the vacuum pumping port, the pressure relief port, and the like are not limited to the positions shown in the figures, and may be located at other positions that meet the functional requirements.

In summary, the present application has the following advantages over the prior technology.

Firstly, according to the application, the local coil immersed in liquid nitrogen is used, so that the signal-to-noise ratio is higher than that of a body coil used as a reception coil.

Secondly, compared with the use of a super-structured surface as a signal amplification tool, the present application uses a high dielectric material to improve the electromagnetic distribution and improve the imaging quality, and can also use other resonant structures to amplify signals.

Thirdly, the cryostat of the application adopts an open design, which is beneficial to the repeated debugging of the radio frequency coil in the manufacturing process.

Fourthly, the radio frequency signal reception system provided by the application is different from the system which only uses a coil under freezing to perform imaging, not only can singly use a barrel coil soaked in liquid nitrogen to perform imaging, but also can be matched with a signal improvement layer to adapt to imaging of parts with different sizes, so as to meet different requirements of signal amplification, electromagnetic distribution improvement and the like. The radio frequency signal reception system capable of improving the imaging performance in various application scenes is formed by combining the radio frequency coil at low temperature with the signal improvement layer.

Lastly, by matching with the resonance circuit, the application can amplify signals for small-size parts with different sizes, such as wrists and arms, so as to improve the image quality. In addition, by using high dielectric materials, the electromagnetic distribution of the measured part can be improved for ultra-high field application scenarios such as 5T and 7T, so as to obtain higher image quality.

Various embodiments of the present application have been described above, and the above description is exemplary, not exhaustive, and is not limited to the disclosed embodiments. Many modifications and variations will be apparent to those of ordinary skill in the art without departing from the scope and spirit of the described embodiments. The terminology used in the application was chosen to best explain the principles of the embodiments, the practical application, or technological improvements in the marketplace, or to enable others of ordinary skill in the art to understand the embodiments disclosed herein. The scope of the application is defined by the claims.

What is claimed is:

1. A radio frequency signal reception system for magnetic resonance imaging, comprising a cryostat, a coil and a pre-amplifier, wherein
the cryostat is provided with a housing, a thermal insulation cover and a vacuum layer which is covered by the housing, the vacuum layer comprises a vacuum region and a closed cavity surrounding the vacuum region, and the vacuum layer is communicated with a first pumping port, the coil is arranged in the closed cavity, and a signal generated by the coil is transmitted to a magnetic resonance system through the pre-amplifier.

2. The system according to claim 1, wherein the insulation cover comprises a cavity, and is provided with a second pumping port, and the cavity of the insulation cover is vacuumized through the second pumping port.

3. The system according to claim 1, wherein the cavity of the insulation cover is filled with a heat insulation material to insulate the heat.

4. The system according to claim 1, wherein the coil is a local coil, liquid nitrogen is injected into the closed cavity to form a liquid nitrogen cavity, and the injected liquid nitrogen is submerged over the coil.

5. The system according to claim 4, wherein the coil is a semi-flexible circuit board on which the coil array and associated circuitry are etched, and the coil is inserted along the liquid nitrogen cavity and then connected end to end.

6. The system according to claim 1, wherein the housing, the insulation cover and the closed cavity are made of non-magnetic non-metallic materials.

7. The system according to claim 6, wherein the non-metallic material comprises a fiberglass or thermoplastic material.

8. The system according to claim 1, wherein the insulation cover is provided with a pressure relief port which passes through the insulation cover and is communicated with the closed cavity, a cable exits through the pressure relief port, and the cable does not completely block the pressure relief port.

9. The system according to claim 1, further comprising, when imaging a target part, overlaying the target part with a signal-enhancing layer made of a resonance circuit or high dielectric material sized to accommodate the target part.

10. The system according to claim 7, wherein the thermoplastic material is a 3D printed material.
